(19) United States
(12) Patent Application Publication
(10) Pub. No.: US 2024/0064987 A1
(43) Pub. Date: Feb. 22, 2024

(54) SILICIDE TRANSISTOR DEVICE AND METHOD

(71) Applicant: Micron Technology, Inc., Boise, ID (US)

(72) Inventors: Toshihiko Miyashita, Higashihiroshima-shi (JP); Ronald Allen Weimer, Boise, ID (US); Dan Mihai Mocuta, Boise, ID (US)

(21) Appl. No.: 17/888,650

(22) Filed: Aug. 16, 2022

(51) Int. Cl. H01L 27/11573; H01L 29/45; H01L 29/78; H01L 27/11529

(52) U.S. Cl. CPC H01L 27/11573; H01L 29/45; H01L 29/7843; H01L 27/11529

(57) ABSTRACT

Apparatus and methods are disclosed, including transistors, semiconductor devices and systems. Example semiconductor devices and methods include silicide contacts on source/drain regions in different conductivity type transistors. In one example, silicide contacts are different between transistors of different conductivity types.

### BACKGROUND

Memory devices are semiconductor circuits that provide electronic storage of data for a host system (e.g., a computer or other electronic device). Memory devices may be volatile or non-volatile. Volatile memory requires power to maintain data, and includes devices such as random-access memory (RAM), static random-access memory (SRAM), dynamic random-access memory (DRAM), or synchronous dynamic random-access memory (SDRAM), among others. Non-volatile memory can retain stored data when not powered, and includes devices such as flash memory, read-only memory (ROM), electrically erasable programmable ROM (EEPROM), erasable programmable ROM (EPROM), resistance variable memory, such as phase change random access memory (PCRAM), resistive random-access memory (RRAM), or magnetoresistive random access memory (MRAM), among others.

Host systems typically include a host processor, a first amount of main memory (e.g., often volatile memory, such as DRAM) to support the host processor, and one or more storage systems (e.g., often non-volatile memory, such as flash memory) that provide additional storage to retain data in addition to or separate from the main memory.

A storage system, such as a solid-state drive (SSD), can include a memory controller and one or more memory devices, including a number of dies or logical units (LUNs). In certain examples, each die can include a number of memory arrays and peripheral circuitry thereon, such as die logic or a die processor. The memory controller can include interface circuitry configured to communicate with a host device (e.g., the host processor or interface circuitry) through a communication interface (e.g., a bidirectional parallel or serial communication interface).

The present description relates generally to transistor structures in complementary metal oxide semiconductor (CMOS) devices and manufacture.

### BRIEF DESCRIPTION OF THE DRAWINGS

In the drawings, which are not necessarily drawn to scale, like numerals may describe similar components in different views. Like numerals having different letter suffixes may represent different instances of similar components. The drawings illustrate generally, by way of example, but not by way of limitation, various embodiments discussed in the present document.

FIG. 1 illustrates a memory device in accordance with some example embodiments.

FIG. 2 illustrates a semiconductor device includes two or more transistors in accordance with some example embodiments.

FIG. 3 illustrates another semiconductor device includes two or more transistors in accordance with some example embodiments.

FIG. 4 illustrates another semiconductor device includes two or more transistors in accordance with some example embodiments.

FIG. 5 illustrates another semiconductor device includes two or more transistors in accordance with some example embodiments.

FIG. 6 illustrates another semiconductor device includes two or more transistors in accordance with some example embodiments.

FIG. 7 illustrates another semiconductor device includes two or more transistors in accordance with some example embodiments.

FIG. 8 illustrates an example method flow diagram in accordance with other example embodiments.

FIG. 9 illustrates an example block diagram of an information handling system in accordance with some example embodiments.

### DETAILED DESCRIPTION

The following description and the drawings sufficiently illustrate specific embodiments to enable those skilled in the art to practice them. Other embodiments may incorporate structural, logical, electrical, process, and other changes. Portions and features of some embodiments may be included in, or substituted for, those of other embodiments. Embodiments set forth in the claims encompass all available equivalents of those claims.

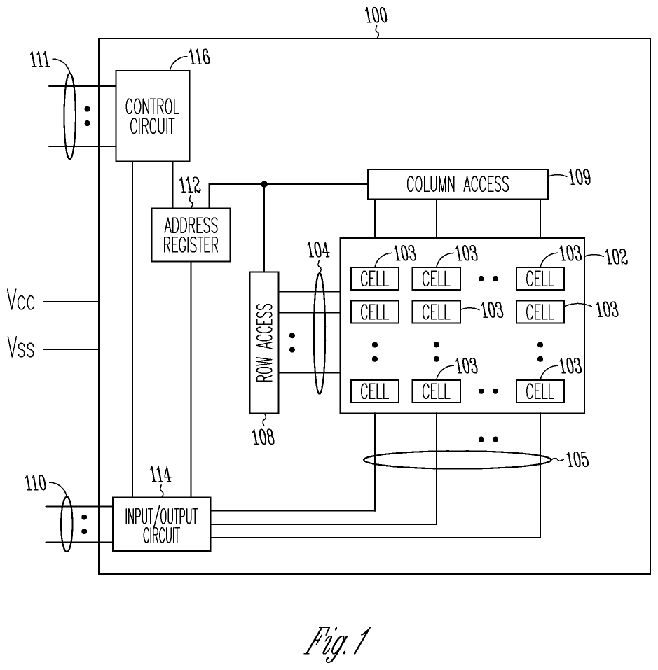

FIG. 1 shows a block diagram of an apparatus in the form of a memory device 100, according to an embodiment of the invention. Memory device 100 can include a memory array 102 having memory cells 103 that can be arranged in rows and columns along with lines (e.g., access lines) 104 and lines (e.g., data lines) 105. Memory device 100 can use lines 104 to access memory cells 103 and lines 105 to exchange information with memory cells 103.

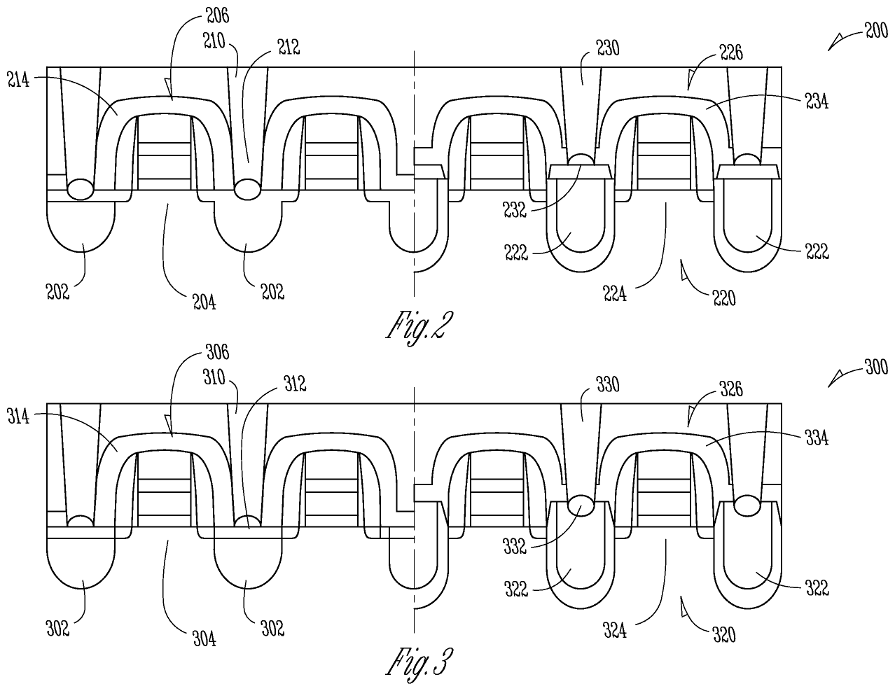

Memory cells 103 and other circuits 114, 116, etc. may include transistors and utilize methods as described in more detail in FIGS. 2-7. In one example, memory arrays 102 include NAND storage array, and peripheral circuits such as circuits 114, 116, 108, 109, etc. may include transistors as described in more detail in FIGS. 2-7.

Row access 108 and column access 109 circuitry can respond to an address register 112 to access memory cells 103 based on row address and column address signals on lines 110, 111, or both. A data input/output circuit 114 can be configured to exchange information between memory cells 103 and lines 110. Lines 110 and 111 can include nodes within memory device 100 or pins (or solder balls) on a package where memory device 100 can reside.

A control circuit 116 can control operations of memory device 100 based on signals present on lines 110 and 111. A device (e.g., a processor or a memory controller) external to memory device 100 can send different commands (e.g., read, write, or erase commands) to memory device 100 using different combinations of signals on lines 110, 111, or both.

Memory device 100 can respond to commands to perform memory operations on memory cells 103, such as performing a read operation to read information from memory cells 103 or performing a write (e.g., programming) operation to store (e.g., program) information into memory cells 103. Memory device 100 can also perform an erase operation to clear information from some or all of memory cells 103.

Memory device 100 can receive a supply voltage, including supply voltages Vcc and Vss. Supply voltage Vss can operate at a ground potential (e.g., having a value of approximately zero volts). Supply voltage Vcc can include an external voltage supplied to memory device 100 from an external power source such as a battery or an alternating-current to direct-current (AC-DC) converter circuitry.

Each of memory cells 103 can be programmed to store information representing a value of a fraction of a bit, a value of a single bit, or a value of multiple bits such as two, three, four, or another number of bits. For example, each of memory cells 103 can be programmed to store information representing a binary value “0” or “1” of a single bit. The single bit per cell is sometimes called a single level cell. In another example, each of memory cells 103 can be programmed to store information representing a value for multiple bits, such as one of four possible values “00,” “01,” “10,” and “11” of two bits, one of eight possible values “000,” “001,” “010,” “011,” “100,” “101,” “110,” and “111” of three bits, or one of other values of another number of multiple bits. A cell that has the ability to store multiple bits is sometimes called a multi-level cell (or multi-state cell).

Memory device 100 can include a non-volatile memory device, and memory cells 103 can include non-volatile memory cells, such that memory cells 103 can retain information stored thereon when power (e.g., Vcc, Vss, or both) is disconnected from memory device 100. For example, memory device 100 can be a flash memory device, such as a NAND flash or a NOR flash memory device, or another kind of memory device, such as a variable resistance memory device (e.g., a phase change or resistive RAM device).

Memory device 100 can include a memory device where memory cells 103 can be physically located in multiple levels on the same device, such that some of memory cells 103 can be stacked over some other memory cells 103 in multiple levels over a substrate (e.g., a semiconductor substrate) of memory device 100.

One of ordinary skill in the art will recognize that memory device 100 may include other elements, several of which are not shown in FIG. 1, so as not to obscure the example embodiments described herein.

FIG. 2 shows a semiconductor device including a first transistor 200 and a second transistor 220. The first transistor 200 includes n-type source/drain regions 202 separated by a first p-type channel 204. A gate stack 206 is formed over the p-type channel 204 to activate the transistor 200 when in operation. Contacts 210 are shown coupled to the n-type source/drain regions 202 by first silicide interface contacts 212. In selected examples, a first liner 214 covers all or a portion of the first transistor 200. Examples of liners 214 include silicon nitride or other materials that can be modified to provide a desired stress/strain state within or adjacent to the channel 204. In one example, the liner 214 provides a tensile strain adjacent to the channel 204. In one example, the liner 214 provides a compressive strain adjacent to the channel 204.

The second transistor 220 includes p-type source/drain regions 222 separated by a second n-type channel 224. A gate stack 226 is formed over the n-type channel 224 to activate the transistor 220 when in operation. Contacts 230 are shown coupled to the p-type source/drain regions 222 by second silicide interface contacts 232. In selected examples, a second liner 234 covers all or a portion of the second transistor 220. Examples of liners 234 include silicon nitride or other materials that can be modified to provide a desired stress/strain state within or adjacent to the channel 224. In one example, the liner 234 provides a tensile strain adjacent to the channel 224. In one example, the liner 234 provides a compressive strain adjacent to the channel 224. In the example of FIG. 2, the first liner 214 and the second liner 234 are the same. In one example, the first liner 214 and the second liner 234 include silicon nitride. In one example, the first liner 214 and the second liner 234 include tensile silicon nitride. In one example, the first liner 214 and the second liner 234 include compressive silicon nitride. In one example, the first liner 214 includes tensile silicon nitride, and the second liner 234 includes compressive nitride.

Material and manufacturing processes in semiconductor fabrication are evolving to include specialized components for p-type and n-type transistors. Technical challenges include thermal stability of structures such as source/drain contacts that may be abutting materials and/or microstructures that react differently. It is desired to improve performance of transistors while also making components that are robust in higher thermal processing conditions. In the example of FIG. 2, the second silicide interface contacts 232 are different from the first silicide interface contacts 212. By using different silicide interface contacts that are tailored to work with different p-type and n-type source/drain regions, performance can be improved while also improving stability at higher processing temperatures.

In the example of FIG. 2, the first silicide interface contacts 212 are at least partially embedded within the n-type source/drain regions 202. Stated another way, the first silicide interface contacts 212 have a through-contact structure. In one example, the first silicide interface contacts 212 include titanium silicide. In one example, the first silicide interface contacts 212 include cobalt silicide. In one example, the n-type source/drain regions 202 include implanted arsenic or implanted phosphorous.

In the example of FIG. 2, the second silicide interface contacts 232 are formed on a whole of the source/drain regions in a self-aligned manner. In the self-aligned second silicide interface contacts 232, the contacts 232 form a flat interface with the p-type source/drain regions 222, in contrast to exhibiting any partial embedding as shown with the first silicide interface contacts 212. In one example, the second silicide interface contacts 232 include nickel platinum silicide. In one example, the second silicide interface contacts 232 include titanium silicide. In one example, the p-type source/drain regions 222 include embedded silicon germanium.

FIGS. 3-7 show a number of different examples of second silicide interface contacts that are different from first silicide interface contacts. Although a number of examples are shown, the examples are not exhaustive. Other configuration combinations of different silicide contacts are also within the scope of the invention.

FIG. 3 shows a semiconductor device including a first transistor 300 and a second transistor 320. The first transistor 300 includes n-type source/drain regions 302 separated by a first p-type channel 304. A gate stack 306 is formed over the p-type channel 304 to activate the transistor 300 when in operation. Contacts 310 are shown coupled to the n-type source/drain regions 302 by first silicide interface contacts 312. In selected examples, a first liner 314 covers all or a portion of the first transistor 300.

The second transistor 320 includes p-type source/drain regions 322 separated by a second n-type channel 324. A gate stack 326 is formed over the n-type channel 324 to activate the transistor 320 when in operation. Contacts 330 are shown coupled to the p-type source/drain regions 322 by second silicide interface contacts 332. In selected examples, a second liner 334 covers all or a portion of the second transistor 320. In the example of FIG. 3, the first liner 314 and the second liner 334 are the same. In one example, the first liner 314 and the second liner 334 include silicon nitride. In one example, the first liner 314 and the second liner 334 include tensile silicon nitride. In one example, the first liner 314 and the second liner 334 include compressive silicon nitride. In one example, the first liner 314 includes tensile silicon nitride, and the second liner 334 includes compressive silicon nitride. In one example, the p-type source/drain regions 322 include embedded silicon germanium.

In the example of FIG. 3, the first silicide interface contacts 312 are formed on a whole of the source/drain region in a self-aligned manner. In the self-aligned first silicide interface contacts 312, the contacts 312 form a flat interface with the n-type source/drain regions 302. In one example, the first silicide interface contacts 312 include titanium silicide. In one example, the first silicide interface contacts 312 include cobalt silicide. In one example, the n-type source/drain regions 302 include implanted arsenic or implanted phosphorous.

In the example of FIG. 3, the second silicide interface contacts 332 are at least partially embedded within the p-type source/drain regions 322. Stated another way, the second silicide interface contacts 332 have a through-contact structure. In the self-aligned first silicide interface contacts 312, the contacts 312 form a flat interface with the n-type source/drain regions 302, in contrast to exhibiting any partial embedding as shown with the first silicide interface contacts 332. In one example, the second silicide interface contacts 332 include nickel platinum silicide. In one example, the second silicide interface contacts 332 include titanium silicide.

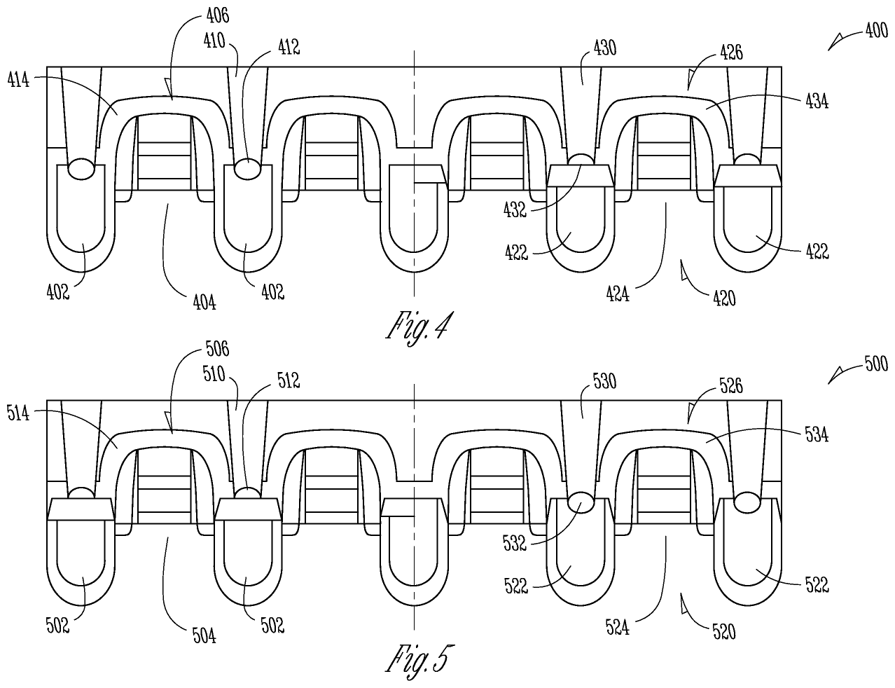

FIG. 4 shows a semiconductor device including a first transistor 400 and a second transistor 420. The first transistor 400 includes n-type source/drain regions 402 separated by a first p-type channel 404. A gate stack 406 is formed over the p-type channel 404 to activate the transistor 400 when in operation. Contacts 410 are shown coupled to the n-type source/drain regions 402 by first silicide interface contacts 412. In selected examples, a first liner 414 covers all or a portion of the first transistor 400.

The second transistor 420 includes p-type source/drain regions 422 separated by a second n-type channel 424. A gate stack 426 is formed over the n-type channel 404 to activate the transistor 420 when in operation. Contacts 430 are shown coupled to the p-type source/drain regions 422 by second silicide interface contacts 432. In selected examples, a second liner 434 covers all or a portion of the second transistor 420. In the example of FIG. 4, the first liner 414 and the second liner 434 are the same. In one example, the first liner 414 and the second liner 434 include silicon nitride. In one example, the first liner 414 and the second liner 434 include tensile silicon nitride. In one example, the first liner 414 and the second liner 434 include compressive silicon nitride. In one example, the first liner 414 includes tensile silicon nitride, and the second liner 434 includes compressive nitride.

In the example of FIG. 4, the first silicide interface contacts 412 are at least partially embedded within the n-type source/drain regions 402. Stated another way, the first silicide interface contacts 412 have a through-contact structure. In one example, the first silicide interface contacts 412 include titanium silicide. In one example, the first silicide interface contacts 412 include cobalt silicide. In one example, the n-type source/drain regions 402 include embedded silicon phosphide.

In the example of FIG. 4, the second silicide interface contacts 432 are formed on a whole of the source/drain regions in a self-aligned manner. In the self-aligned second silicide interface contacts 432, the contacts 432 form a flat interface with the p-type source/drain regions 422, in contrast to exhibiting any partial embedding as shown with the first silicide interface contacts 412. In one example, the second silicide interface contacts 432 include nickel platinum silicide. In one example, the second silicide interface contacts 432 include titanium silicide. In one example, the p-type source/drain regions 422 include embedded silicon germanium.

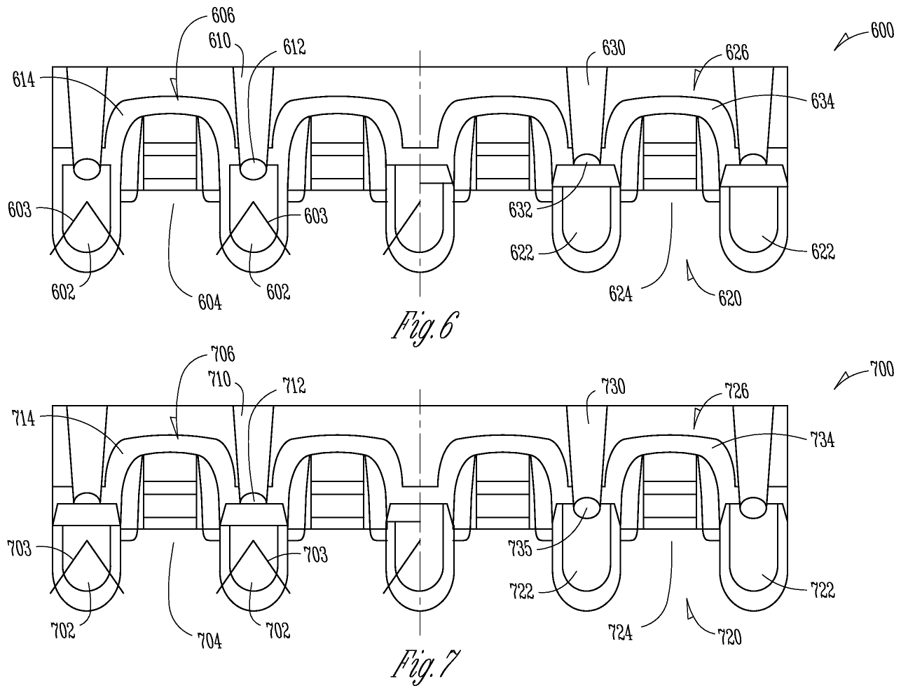

FIG. 5 shows a semiconductor device including a first transistor 500 and a second transistor 520. The first transistor 500 includes n-type source/drain regions 502 separated by a first p-type channel 504. A gate stack 506 is formed over the p-type channel 504 to activate the transistor 400 when in operation. Contacts 510 are shown coupled to the n-type source/drain regions 402 by first silicide interface contacts 512. In selected examples, a first liner 514 covers all or a portion of the first transistor 500.

The second transistor 520 includes p-type source/drain regions 522 separated by a second n-type channel 524. A gate stack 526 is formed over the n-type channel 504 to activate the transistor 520 when in operation. Contacts 530 are shown coupled to the p-type source/drain regions 522 by second silicide interface contacts 532. In selected examples, a second liner 534 covers all or a portion of the second transistor 520. In the example of FIG. 5, the first liner 514 and the second liner 534 are the same. In one example, the first liner 514 and the second liner 534 include silicon nitride. In one example, the first liner 514 and the second liner 534 include tensile silicon nitride. In one example, the first liner 514 and the second liner 534 include compressive silicon nitride. In one example, the first liner 514 includes tensile silicon nitride, and the second liner 534 includes compressive nitride.

In the example of FIG. 5, the first silicide interface contacts 512 are formed on a whole of the source/drain regions in a self-aligned manner. In the self-aligned second silicide interface contacts 512, the contacts 512 form a flat interface with the n-type source/drain regions 502. In one example, the first silicide interface contacts 512 include titanium silicide. In one example, the first silicide interface contacts 512 include cobalt silicide. In one example, the n-type source/drain regions 502 include embedded silicon phosphide.

In the example of FIG. 5, the second silicide interface contacts 532 are at least partially embedded within the p-type source/drain regions 522. Stated another way, the second silicide interface contacts 532 have a through-contact structure. In the self-aligned second silicide interface contacts 512, the contacts 512 form a flat interface with the n-type source/drain regions 502, in contrast to exhibiting any partial embedding as shown with the second silicide interface contacts 532. In one example, the second silicide interface contacts 532 include nickel platinum silicide. In one example, the second silicide interface contacts 532 include titanium silicide. In one example, the p-type source/drain regions 522 include embedded silicon germanium.

FIG. 6 shows a semiconductor device including a first transistor 600 and a second transistor 620. The first transistor 600 includes n-type source/drain regions 602 separated by a first p-type channel 604. A gate stack 606 is formed over the p-type channel 604 to activate the transistor 600 when in operation. Contacts 610 are shown coupled to the n-type source/drain regions 602 by first silicide interface contacts 612. In selected examples, a first liner 614 covers all or a portion of the first transistor 600.

The second transistor 620 includes p-type source/drain regions 622 separated by a second n-type channel 624. A gate stack 626 is formed over the n-type channel 604 to activate the transistor 620 when in operation. Contacts 630 are shown coupled to the p-type source/drain regions 622 by second silicide interface contacts 632. In selected examples, a second liner 634 covers all or a portion of the second transistor 620.

In the example of FIG. 6, the first liner 614 and the second liner 634 are different. In one example, the first liner 614 and the second liner 634 include silicon nitride. In one example, the first liner 614 includes tensile silicon nitride. In one example, the second liner 634 includes compressive silicon nitride. The use of different liners over different conductivity types of transistor channels (p-type or n-type) provides conductivity enhancements that are matched to the conductivity type. For example, a compressive liner 634 may enhance an n-type channel 624, but not a p-type channel 604. As such, in the example of FIG. 6, the liner types (614, 634) are chosen to match the channel types.

In the example of FIG. 6, the first transistor 600 includes dislocations 603 adjacent to the channel 604. In one example, the dislocations 603 are formed using a dislocation stress memorization technique (DSMT). The use of dislocation 603 may also be specific to a channel conductivity type. As such, in the example of FIG. 6, the presence or absence of dislocations 603 may be chosen to match the channel types.

In the example of FIG. 6, the first silicide interface contacts 612 are at least partially embedded within the n-type source/drain regions 602. Stated another way, the first silicide interface contacts 612 have a through-contact structure. In one example, the first silicide interface contacts 612 include titanium silicide. In one example, the first silicide interface contacts 612 include cobalt silicide. In one example, the n-type source/drain regions 602 include embedded silicon phosphide.

In the example of FIG. 6, the second silicide interface contacts 632 are formed on a whole of the source/drain regions in a self-aligned manner. In the self-aligned second silicide interface contacts 632, the contacts 632 form a flat interface with the p-type source/drain regions 622, in contrast to exhibiting any partial embedding as shown with the first silicide interface contacts 612. In one example, the second silicide interface contacts 632 include nickel platinum silicide. In one example, the second silicide interface contacts 632 include titanium silicide. In one example, the p-type source/drain regions 622 include embedded silicon germanium.

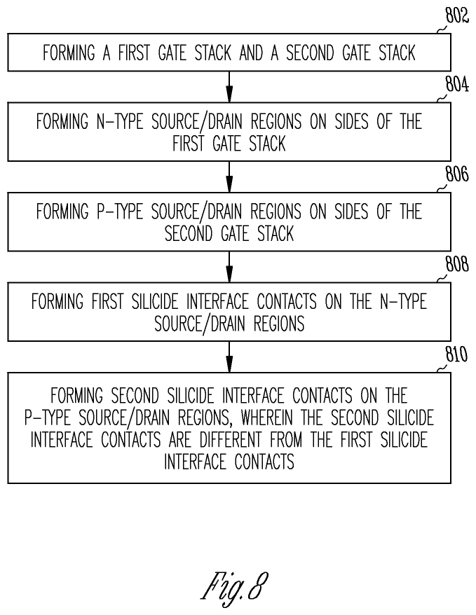

FIG. 7 shows a semiconductor device including a first transistor 700 and a second transistor 720. The first transistor 700 includes n-type source/drain regions 702 separated by a first p-type channel 704. A gate stack 706 is formed over the p-type channel 704 to activate the transistor 700 when in operation. Contacts 710 are shown coupled to the n-type source/drain regions 702 by first silicide interface contacts 712. In selected examples, a first liner 714 covers all or a portion of the first transistor 700.

The second transistor 720 includes p-type source/drain regions 722 separated by a second n-type channel 724. A gate stack 726 is formed over the n-type channel 704 to activate the transistor 720 when in operation. Contacts 730 are shown coupled to the p-type source/drain regions 722 by second silicide interface contacts 732. In selected examples, a second liner 734 covers all or a portion of the second transistor 720.

In the example of FIG. 7, the first liner 714 and the second liner 734 are different. In one example, the first liner 714 and the second liner 734 include silicon nitride. In one example, the first liner 714 includes tensile silicon nitride. In one example, the second liner 734 includes compressive silicon nitride. The use of different liners over different conductivity types of transistor channels (p-type or n-type) provides conductivity enhancements that are matched to the conductivity type. For example, a compressive liner 734 may enhance an n-type channel 724, but not a p-type channel 704. As such, in the example of FIG. 7, the liner types (714, 734) are chosen to match the channel types.

In the example of FIG. 7, the first transistor 700 includes dislocations 703 adjacent to the channel 704. In one example, the dislocations 703 are formed using a dislocation stress memorization technique (DSMT). The use of dislocation 703 may also be specific to a channel conductivity type. As such, in the example of FIG. 7, the presence or absence of dislocations 703 may be chosen to match the channel types.

In the example of FIG. 7, the first silicide interface contacts 712 are formed on a whole of the source/drain regions in a self-aligned manner. In the self-aligned second silicide interface contacts 712, the contacts 712 form a flat interface with the n-type source/drain regions 702. In one example, the first silicide interface contacts 712 include titanium silicide. In one example, the first silicide interface contacts 712 include cobalt silicide. In one example, the n-type source/drain regions 702 include embedded silicon phosphide.

In the example of FIG. 7, the second silicide interface contacts 732 are at least partially embedded within the n-type source/drain regions 722. Stated another way, the second silicide interface contacts 732 have a through-contact structure. In the self-aligned second silicide interface contacts 712, the contacts 712 form a flat interface with the n-type source/drain regions 702, in contrast to exhibiting any partial embedding as shown with the first silicide interface contacts 732. In one example, the second silicide interface contacts 732 include nickel platinum silicide. In one example, the second silicide interface contacts 732 include titanium silicide. In one example, the p-type source/drain regions 722 include embedded silicon germanium.

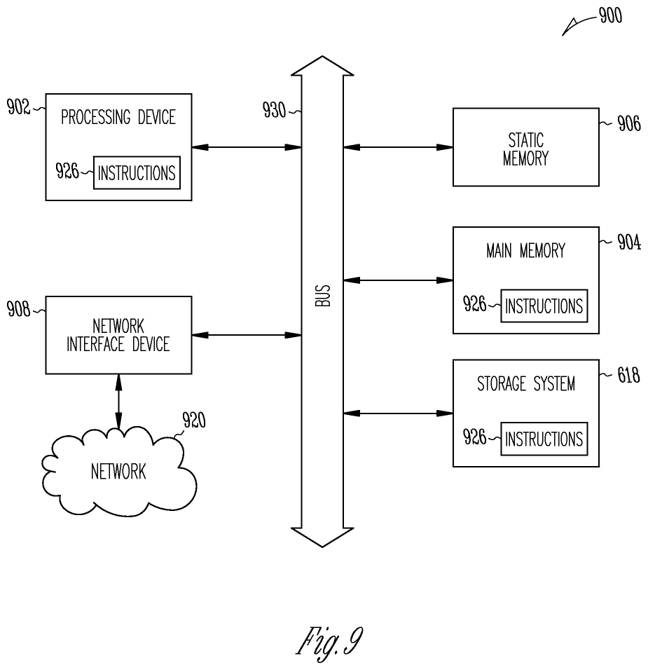

FIG. 8 shows a flow diagram of one example method of manufacture. In operation 802, a first gate stack and a second gate stack are formed. In operation 804, n-type source/drain regions are formed on sides of the first gate stack. In operation 806, p-type source/drain regions are formed on sides of the second gate stack. In operation 808, first silicide interface contacts are formed on the n-type source/drain regions, and in operation 810, second silicide interface contacts are formed on the p-type source/drain regions, wherein the second silicide interface contacts are different from the first silicide interface contacts.

FIG. 9 illustrates a block diagram of an example machine (e.g., a host system) 900 which may include one or more transistors, memory devices and/or memory systems as described above. As discussed above, machine 900 may benefit from enhanced memory performance from use of one or more of the described transistor structures and/or memory systems, facilitating improved performance of machine 900 (as for many such machines or systems, efficient reading and writing of memory can facilitate improved performance of a processor or other components that machine, as described further below.

In alternative embodiments, the machine 900 may operate as a standalone device or may be connected (e.g., networked) to other machines. In a networked deployment, the machine 900 may operate in the capacity of a server machine, a client machine, or both in server-client network environments. In an example, the machine 900 may act as a peer machine in peer-to-peer (P2P) (or other distributed) network environment. The machine 900 may be a personal computer (PC), a tablet PC, a set-top box (STB), a personal digital assistant (PDA), a mobile telephone, a web appliance, an IoT device, automotive system, or any machine capable of executing instructions (sequential or otherwise) that specify actions to be taken by that machine. Further, while only a single machine is illustrated, the term “machine” shall also be taken to include any collection of machines that individually or jointly execute a set (or multiple sets) of instructions to perform any one or more of the methodologies discussed herein, such as cloud computing, software as a service (SaaS), other computer cluster configurations.

Examples, as described herein, may include, or may operate by, logic, components, devices, packages, or mechanisms. Circuitry is a collection (e.g., set) of circuits implemented in tangible entities that include hardware (e.g., simple circuits, gates, logic, etc.). Circuitry membership may be flexible over time and underlying hardware variability. Circuitries include members that may, alone or in combination, perform specific tasks when operating. In an example, hardware of the circuitry may be immutably designed to carry out a specific operation (e.g., hardwired). In an example, the hardware of the circuitry may include variably connected physical components (e.g., execution units, transistors, simple circuits, etc.) including a computer-readable medium physically modified (e.g., magnetically, electrically, moveable placement of invariant massed particles, etc.) to encode instructions of the specific operation. In connecting the physical components, the underlying electrical properties of a hardware constituent are changed, for example, from an insulator to a conductor or vice versa. The instructions enable participating hardware (e.g., the execution units or a loading mechanism) to create members of the circuitry in hardware via the variable connections to carry out portions of the specific tasks when in operation. Accordingly, the computer-readable medium is communicatively coupled to the other components of the circuitry when the device is operating. In an example, any of the physical components may be used in more than one member of more than one circuitry. For example, under operation, execution units may be used in a first circuit of a first circuitry at one point in time and reused by a second circuit in the first circuitry, or by a third circuit in a second circuitry at a different time.

The machine (e.g., computer system, a host system, etc.) 900 may include a processing device 902 (e.g., a hardware processor, a central processing unit (CPU), a graphics processing unit (GPU), a hardware processor core, or any combination thereof, etc.), a main memory 904 (e.g., read-only memory (ROM), dynamic random-access memory (DRAM) such as synchronous DRAM (SDRAM) or Rambus DRAM (RDRAM), etc.), a static memory 906 (e.g., static random-access memory (SRAM), etc.), and a storage system 918, some or all of which may communicate with each other via a communication interface (e.g., a bus) 930. In one example, the main memory 904 includes one or more memory devices as described in examples above.

The processing device 902 can represent one or more general-purpose processing devices such as a microprocessor, a central processing unit, or the like. More particularly, the processing device can be a complex instruction set computing (CISC) microprocessor, reduced instruction set computing (RISC) microprocessor, very long instruction word (VLIW) microprocessor, or a processor implementing other instruction sets, or processors implementing a combination of instruction sets. The processing device 902 can also be one or more special-purpose processing devices such as an application specific integrated circuit (ASIC), a field programmable gate array (FPGA), a digital signal processor (DSP), network processor, or the like. The processing device 902 can be configured to execute instructions 926 for performing the operations and steps discussed herein. The computer system 900 can further include a network interface device 908 to communicate over a network 920.

The storage system 918 can include a machine-readable storage medium (also known as a computer-readable medium) on which is stored one or more sets of instructions 926 or software embodying any one or more of the methodologies or functions described herein. The instructions 926 can also reside, completely or at least partially, within the main memory 904 or within the processing device 902 during execution thereof by the computer system 900, the main memory 904 and the processing device 902 also constituting machine-readable storage media.

The term “machine-readable storage medium” should be taken to include a single medium or multiple media that store the one or more sets of instructions, or any medium that is capable of storing or encoding a set of instructions for execution by the machine and that cause the machine to perform any one or more of the methodologies of the present disclosure. The term “machine-readable storage medium” shall accordingly be taken to include, but not be limited to, solid-state memories, optical media, and magnetic media. In an example, a massed machine-readable medium comprises a machine-readable medium with multiple particles having invariant (e.g., rest) mass. Accordingly, massed machine-readable media are not transitory propagating signals. Specific examples of massed machine-readable media may include: non-volatile memory, such as semiconductor memory devices (e.g., Electrically Programmable Read-Only Memory (EPROM), Electrically Erasable Programmable Read-Only Memory (EEPROM)) and flash memory devices; magnetic disks, such as internal hard disks and removable disks; magneto-optical disks; and CD-ROM and DVD-ROM disks.

The machine 900 may further include a display unit, an alphanumeric input device (e.g., a keyboard), and a user interface (UI) navigation device (e.g., a mouse). In an example, one or more of the display unit, the input device, or the UI navigation device may be a touch screen display. The machine a signal generation device (e.g., a speaker), or one or more sensors, such as a global positioning system (GPS) sensor, compass, accelerometer, or one or more other sensor. The machine 900 may include an output controller, such as a serial (e.g., universal serial bus (USB), parallel, or other wired or wireless (e.g., infrared (IR), near field communication (NFC), etc.) connection to communicate or control one or more peripheral devices (e.g., a printer, card reader, etc.).

The instructions 926 (e.g., software, programs, an operating system (OS), etc.) or other data are stored on the storage system 918 can be accessed by the main memory 904 for use by the processing device 902. The main memory 904 (e.g., DRAM) is typically fast, but volatile, and thus a different type of storage than the storage system 918 (e.g., an SSD), which is suitable for long-term storage, including while in an “off” condition. The instructions 926 or data in use by a user or the machine 900 are typically loaded in the main memory 904 for use by the processing device 902. When the main memory 904 is full, virtual space from the storage system 918 can be allocated to supplement the main memory 904; however, because the storage system 918 device is typically slower than the main memory 904, and write speeds are typically at least twice as slow as read speeds, use of virtual memory can greatly reduce user experience due to storage system latency (in contrast to the main memory 904, e.g., DRAM). Further, use of the storage system 918 for virtual memory can greatly reduce the usable lifespan of the storage system 918.

The instructions 924 may further be transmitted or received over a network 920 using a transmission medium via the network interface device 908 utilizing any one of a number of transfer protocols (e.g., frame relay, internet protocol (IP), transmission control protocol (TCP), user datagram protocol (UDP), hypertext transfer protocol (HTTP), etc.). Example communication networks may include a local area network (LAN), a wide area network (WAN), a packet data network (e.g., the Internet), mobile telephone networks (e.g., cellular networks), Plain Old Telephone (POTS) networks, and wireless data networks (e.g., Institute of Electrical and Electronics Engineers (IEEE) 802.15 family of standards known as Wi-Fi®, IEEE 802.16 family of standards known as WiMax®, IEEE 802.15.4 family of standards, peer-to-peer (P2P) networks, among others. In an example, the network interface device 908 may include one or more physical jacks (e.g., Ethernet, coaxial, or phone jacks) or one or more antennas to connect to the network 920. In an example, the network interface device 908 may include multiple antennas to wirelessly communicate using at least one of single-input multiple-output (SIMO), multiple-input multiple-output (MIMO), or multiple-input single-output (MISO) techniques. The term “transmission medium” shall be taken to include any intangible medium that is capable of storing, encoding, or carrying instructions for execution by the machine 900, and includes digital or analog communications signals or other intangible medium to facilitate communication of such software.

The above detailed description includes references to the accompanying drawings, which form a part of the detailed description. The drawings show, by way of illustration, specific embodiments in which the invention can be practiced. These embodiments are also referred to herein as “examples”. Such examples can include elements in addition to those shown or described. However, the present inventor also contemplates examples in which only those elements shown or described are provided. Moreover, the present inventor also contemplates examples using any combination or permutation of those elements shown or described (or one or more aspects thereof), either with respect to a particular example (or one or more aspects thereof), or with respect to other examples (or one or more aspects thereof) shown or described herein.

All publications, patents, and patent documents referred to in this document are incorporated by reference herein in their entirety, as though individually incorporated by reference. In the event of inconsistent usages between this document and those documents so incorporated by reference, the usage in the incorporated reference(s) should be considered supplementary to that of this document; for irreconcilable inconsistencies, the usage in this document controls.

In this document, the terms “a” or “an” are used, as is common in patent documents, to include one or more than one, independent of any other instances or usages of “at least one” or “one or more.” In this document, the term “or” is used to refer to a nonexclusive or, such that “A or B” includes “A but not B,” “B but not A,” and “A and B,” unless otherwise indicated. In the appended claims, the terms “including” and “in which” are used as the plain-English equivalents of the respective terms “comprising” and “wherein”. Also, in the following claims, the terms “including” and “comprising” are open-ended, that is, a system, device, article, or process that includes elements in addition to those listed after such a term in a claim are still deemed to fall within the scope of that claim. Moreover, in the following claims, the terms “first,” “second,” and “third,” etc. are used merely as labels, and are not intended to impose numerical requirements on their objects.

In various examples, the components, controllers, processors, units, engines, or tables described herein can include, among other things, physical circuitry or firmware stored on a physical device. As used herein, “processor” means any type of computational circuit such as, but not limited to, a microprocessor, a microcontroller, a graphics processor, a digital signal processor (DSP), or any other type of processor or processing circuit, including a group of processors or multi-core devices.

The term “horizontal” as used in this document is defined as a plane parallel to the conventional plane or surface of a substrate, such as that underlying a wafer or die, regardless of the actual orientation of the substrate at any point in time. The term “vertical” refers to a direction perpendicular to the horizontal as defined above. Prepositions, such as “on,” “over,” and “under” are defined with respect to the conventional plane or surface being on the top or exposed surface of the substrate, regardless of the orientation of the substrate; and while “on” is intended to suggest a direct contact of one structure relative to another structure which it lies “on” (in the absence of an express indication to the contrary); the terms “over” and “under” are expressly intended to identify a relative placement of structures (or layers, features, etc.), which expressly includes-but is not limited to-direct contact between the identified structures unless specifically identified as such. Similarly, the terms “over” and “under” are not limited to horizontal orientations, as a structure may be “over” a referenced structure if it is, at some point in time, an outermost portion of the construction under discussion, even if such structure extends vertically relative to the referenced structure, rather than in a horizontal orientation.

The terms “wafer” is used herein to refer generally to any structure on which integrated circuits are formed, and also to such structures during various stages of integrated circuit fabrication. The term “substrate” is used to refer to either a wafer, or other structures which support or connect to other components, such as memory die or portions thereof. Thus, the term “substrate” embraces, for example, circuit or “PC” boards, interposers, and other organic or non-organic supporting structures (which in some cases may also contain active or passive components). The following detailed description is, therefore, not to be taken in a limiting sense, and the scope of the various embodiments is defined only by the appended claims, along with the full scope of equivalents to which such claims are entitled.

It will be understood that when an element is referred to as being “on,” “connected to” or “coupled with” another element, it can be directly on, connected, or coupled with the other element or intervening elements may be present. In contrast, when an element is referred to as being “directly on,” “directly connected to” or “directly coupled with” another element, there are no intervening elements or layers present. If two elements are shown in the drawings with a line connecting them, the two elements can be either be coupled, or directly coupled, unless otherwise indicated.

Method examples described herein can be machine or computer-implemented at least in part. Some examples can include a computer-readable medium or machine-readable medium encoded with instructions operable to configure an electronic device to perform methods as described in the above examples. An implementation of such methods can include code, such as microcode, assembly language code, a higher-level language code, or the like. Such code can include computer-readable instructions for performing various methods. The code may form portions of computer program products. Further, the code can be tangibly stored on one or more volatile or non-volatile tangible computer-readable media, such as during execution or at other times. Examples of these tangible computer-readable media can include, but are not limited to, hard disks, removable magnetic disks, removable optical disks (e.g., compact disks and digital video disks), magnetic cassettes, memory cards or sticks, random access memories (RAMS), read only memories (ROMs), and the like.

To better illustrate the method and apparatuses disclosed herein, a non-limiting list of embodiments is provided here:

Example 1 is a semiconductor device. The device includes a first transistor having n-type source/drain regions separated by a first channel, a second transistor having p-type source/drain regions separated by a second channel, a first silicide interface contact on the n-type source/drain regions, and a second silicide interface contact on the p-type source/drain regions different from the first silicide interface contact.

In Example 2, the semiconductor device of Example 1 optionally includes wherein the n-type source/drain regions include embedded silicon phosphorous.

In Example 3, the semiconductor device of any one of Examples 1-2 optionally includes wherein the first silicide interface contact penetrates into a portion of the n-type source/drain regions.

In Example 4, the semiconductor device of any one of Examples 1-3 optionally includes wherein the first silicide interface contact includes a self-aligned silicide interface contact.

In Example 5, the semiconductor device of any one of Examples 1˜4 optionally further includes an intermediate layer between the self-aligned silicide interface contact and a contact via.

In Example 6, the semiconductor device of any one of Examples 1-5 optionally includes wherein the p-type source/drain regions include embedded silicon germanium.

In Example 7, the semiconductor device of any one of Examples 1-6 optionally includes wherein the second silicide interface contact penetrates into a portion of the n-type source/drain regions.

In Example 8, the semiconductor device of any one of Examples 1-7 optionally includes wherein the second silicide interface contact includes a self-aligned silicide interface contact.

In Example 9, the semiconductor device of any one of Examples 1-8 optionally further includes an intermediate layer between the self-aligned silicide interface contact and a contact via.

Example 10 is a memory device. The memory device includes an array of memory cells and peripheral circuitry adjacent to the array of memory cells. The peripheral circuitry includes a first transistor having n-type source/drain regions separated by a first channel, a second transistor having p-type source/drain regions separated by a second channel, a first silicide interface contact on the n-type source/drain regions, and a second silicide interface contact on the p-type source/drain regions different from the first silicide interface contact.

In Example 11, the memory device of Example 10 optionally further includes a silicon nitride liner over one or more of the first and second transistors.

In Example 12, the memory device of any one of Examples 10-11 optionally further includes a tensile silicon nitride liner over at least a portion of the first transistor.

In Example 13, the memory device of any one of Examples 10-12 optionally further includes dislocations in the n-type source/drain regions of the first transistor.

In Example 14, the memory device of any one of Examples 10-13 optionally further includes a compressive silicon nitride liner over at least a portion of the second transistor.

Example 15 is a method of forming a semiconductor device. The method includes forming a first gate stack and a second gate stack, forming n-type source/drain regions on sides of the first gate stack, forming p-type source/drain regions on sides of the second gate stack, forming first silicide interface contacts on the n-type source/drain regions, and forming second silicide interface contacts on the p-type source/drain regions, wherein the second silicide interface contacts are different from the first silicide interface contacts.

In Example 16, the method of Example 15 optionally includes wherein forming n-type source/drain regions includes epitaxial growth of embedded n-type source/drain regions.

In Example 17, the method of any one of Examples 15-16 optionally includes wherein forming p-type source/drain regions includes epitaxial growth of embedded p-type source/drain regions.

In Example 18, the method of any one of Examples 15-17 optionally includes wherein forming n-type source/drain regions includes annealing doped n-type source/drain regions to induce strain and form dislocations.

In Example 19, the method of any one of Examples 15-18 optionally includes wherein forming first silicide interface contacts includes self-aligned formation of first silicide interface contacts.

In Example 20, the method of any one of Examples 15-19 optionally includes wherein forming first silicide interface contacts includes forming a silicide that includes titanium.

In Example 21, the method of any one of Examples 15-20 optionally includes wherein forming first silicide interface contacts includes forming a silicide that includes cobalt.

In Example 22, the method of any one of Examples 15-21 optionally includes wherein forming second silicide interface contacts includes self-aligned formation of second silicide interface contacts.

In Example 23, the method of any one of Examples 15-22 optionally includes wherein forming first silicide interface contacts includes forming a silicide that includes titanium.

In Example 24, the method of any one of Examples 15-23 optionally includes wherein forming first silicide interface contacts includes forming a silicide that includes platinum and nickel.

The above description is intended to be illustrative, and not restrictive. For example, the above-described examples (or one or more aspects thereof) may be used in combination with each other. Other embodiments can be used, such as by one of ordinary skill in the art upon reviewing the above description. The Abstract is provided to comply with 37 C.F.R. § 1.72(b), to allow the reader to quickly ascertain the nature of the technical disclosure. It is submitted with the understanding that it will not be used to interpret or limit the scope or meaning of the claims. Also, in the above Detailed Description, various features may be grouped together to streamline the disclosure. This should not be interpreted as intending that an unclaimed disclosed feature is essential to any claim. Rather, inventive subject matter may lie in less than all features of a particular disclosed embodiment. Thus, the following claims are hereby incorporated into the Detailed Description, with each claim standing on its own as a separate embodiment, and it is contemplated that such embodiments can be combined with each other in various combinations or permutations. The scope of the invention should be determined with reference to the appended claims, along with the full scope of equivalents to which such claims are entitled.

What is claimed is:

1. A semiconductor device, comprising:
a first transistor having n-type source/drain regions separated by a first channel;
a second transistor having p-type source/drain regions separated by a second channel;
a first silicide interface contact on the n-type source/drain regions; and
a second silicide interface contact on the p-type source/drain regions different from the first silicide interface contact.

2. The semiconductor device of claim 1, wherein the n-type source/drain regions include embedded silicon phosphorous.

3. The semiconductor device of claim 1, wherein the first silicide interface contact penetrates into a portion of the n-type source/drain regions.

4. The semiconductor device of claim 1, wherein the first silicide interface contact includes a self-aligned silicide interface contact.

5. The semiconductor device of claim 4, further including an intermediate layer between the self-aligned silicide interface contact and a contact via.

6. The semiconductor device of claim 1, wherein the p-type source/drain regions include embedded silicon germanium.

7. The semiconductor device of claim 1, wherein the second silicide interface contact penetrates into a portion of the n-type source/drain regions.

8. The semiconductor device of claim 1, wherein the second silicide interface contact includes a self-aligned silicide interface contact.

9. The semiconductor device of claim 8, further including an intermediate layer between the self-aligned silicide interface contact and a contact via.

10. A memory device comprising:
an array of memory cells;
peripheral circuitry adjacent to the array of memory cells, the peripheral circuitry including;
a first transistor having n-type source/drain regions separated by a first channel;
a second transistor having p-type source/drain regions separated by a second channel;
a first silicide interface contact on the n-type source/drain regions; and
a second silicide interface contact on the p-type source/drain regions different from the first silicide interface contact.

11. The memory device of claim 10, further including a silicon nitride liner over one or more of the first and second transistors.

12. The memory device of claim 10, further including a tensile silicon nitride liner over at least a portion of the first transistor.

13. The memory device of claim 12, further including dislocations in the n-type source/drain regions of the first transistor.

14. The memory device of claim 12, further including a compressive silicon nitride liner over at least a portion of the second transistor.

15. A method of forming a semiconductor device, comprising:
forming a first gate stack and a second gate stack;
forming n-type source/drain regions on sides of the first gate stack;
forming p-type source/drain regions on sides of the second gate stack;
forming first silicide interface contacts on the n-type source/drain regions; and
forming second silicide interface contacts on the p-type source/drain regions, wherein the second silicide interface contacts are different from the first silicide interface contacts.

16. The method of claim 15, wherein forming n-type source/drain regions includes epitaxial growth of embedded n-type source/drain regions.

17. The method of claim 15, wherein forming p-type source/drain regions includes epitaxial growth of embedded p-type source/drain regions.

18. The method of claim 15, wherein forming n-type source/drain regions includes annealing doped n-type source/drain regions to induce strain and form dislocations.

19. The method of claim 15, wherein forming first silicide interface contacts includes self-aligned formation of first silicide interface contacts.

20. The method of claim 19, wherein forming first silicide interface contacts includes forming a silicide that includes titanium.

21. The method of claim 19, wherein forming first silicide interface contacts includes forming a silicide that includes cobalt.

22. The method of claim 15, wherein forming second silicide interface contacts includes self-aligned formation of second silicide interface contacts.

23. The method of claim 22, wherein forming first silicide interface contacts includes forming a silicide that includes titanium.

24. The method of claim 22, wherein forming first silicide interface contacts includes forming a silicide that includes platinum and nickel.
